(19) United States
(12) Patent Application Publication
(10) Pub. No.: US 2007/0141822 A1
(43) Pub. Date: Jun. 21, 2007

(54) MULTI-STEP ANNEAL METHOD

(76) Inventors: Jiann-Fu Chen, Hsinchu City (TW); Meng-Hsiu Ho, Hsinchu City (TW); Chun-Ting Hu, Hsinchu City (TW); Chun-Hua Chang, Nantou County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,051

(22) Filed: Dec. 15, 2005

(51) Int. Cl. H01L 21/44

(52) U.S. Cl. 438/597

(57) ABSTRACT

A multi-step anneal method is provided. First, a substrate is provided. Then, a dielectric layer comprising a damascene structure is formed over the substrate, and a barrier/seed layer is formed over the damascene structure. Next, a metal layer is formed over the barrier layer, and performing a first anneal step in-situ to anneal the substrate at a first temperature range with a first environment. Thereafter, a metal chemical mechanical polish (CMP) step is performed to remove a portion of the metal layer until a portion of the barrier layer is exposed. Then, a second anneal step is performed to anneal the substrate at a second temperature range with a second environment.

### BACKGROUND OF THE INVENTION

1. Field of the Invention

The present invention is related to a multi-step anneal method. More particularly, the present invention is related to a multi-step anneal method for reducing the hillocks of the semiconductor structure.

2. Description of Related Art

Recently, as the semiconductor technology advances, the semiconductor device is developed with higher density, larger integration and better performance. In order to increase the integration and the density of the semiconductor device, the line width of the semiconductor structure is narrowed gradually. Therefore, in the formation of interconnection lines in a semiconductor structure, the conventional method of using aluminum as the material for the interconnection lines is gradually replaced by a method of using copper for the interconnection lines. Accordingly, the resistance-capacitance (RC) constant of the semiconductor structure is reduced and thus the operational speed thereof is enhanced since the resistance of copper is lower than that of aluminum.

However, as the interconnection lines are formed by copper in a metallization process, a variety of corresponding processes such as the etching process and the planarization process need to be developed and modified. FIGS. 1A-1B are schematic cross-sectional views in fabrication process of a conventional copper dual damascene structure. Hereinafter, the metallization process will be described with respect to FIGS. 1A-1B, which have been disclosed in U.S. Pat. No. 6,391,777.

Referring to FIG. 1A, a conventional copper damascene structure 100 includes a substrate 102, an inter-metal dielectric (IMD) layer 104, a barrier layer 106, a seed layer 108 and a copper layer 110. The copper layer 110 is deposited over the substrate 102 without being planarized yet. At this stage, a first annealing process 112 with a temperature of 200° C. to 250° C. for 1 to 2 minutes. Then, the copper layer 110 is planarized. The copper damascene structure 100 shown in FIG. 1B is formed after the planarization process such as the chemical mechanical polishing (CMP) process. Conventionally, the copper layer 110 is formed by using an electrochemical plating (ECP) process. Thereafter, the copper layer 110 is annealed again by a second annealing process 114 at a temperature in a range of 350° C. to 450° C. for 25 to 35 minutes, in which the temperature of the second annealing process 114 is higher than the first annealing process 112. In general, the grain growth of the copper layer 110 after the first annealing is not stable, for example, the difference between the size of the copper grain is large. Therefore, the subsequent copper CMP process is easily out of control.

In addition, referring to FIG. 1B, when the following process such as forming another layer over the surface of the substrate is performed after the CMP process is conducted, many problems are generated. For example, a variety of hillocks are generated between the surface of the copper 110 and the another layer formed thereon since the tensile stress of the copper layer is high and not uniform. Therefore, the interface between the surface of the copper layer 110 and the another layer is not smooth, and thus the reliability and the performance of the copper damascene structure 100 are reduced. Accordingly, an external treatment for the copper damascene structure 100 to solve the problems described above is desired.

### SUMMARY OF THE INVENTION

Accordingly, the present invention is directed to a multi-step anneal method for stabilizing the grain growth of the metal layer and releasing the tensile stress of the metal layer. Therefore, the hillocks of the semiconductor structure are reduced and the metal CMP process is easily controlled.

The present invention is also directed to a multi-step anneal method for providing a close loop controlled (CLC) measurement to control the thickness and the polishing time of the layers of the substrate. Therefore, the metal resistance (Rs) of the structure may also be controlled.

In accordance with one embodiment of the present invention, a multi-step anneal method is provided. First, a substrate is provided. Then, a dielectric layer comprising a damascene structure is formed over the substrate, and a barrier/seed layer is formed over the damascene structure. Thereafter, a metal layer is formed over the barrier layer, and a first anneal step is performed in-situ to anneal the substrate at a first temperature range in a first environment. Thereafter, a metal chemical mechanical polish (CMP) step is performed to remove a portion of the metal layer until a portion of the barrier layer is exposed. Then, a second anneal step is performed to anneal the substrate at a second temperature range in a second environment.

In one embodiment of the present invention, a barrier CMP step is performed to remove the portion of the barrier layer and a surface of the metal layer until a portion of dielectric layer is exposed after the second anneal step is performed.

In one embodiment of the present invention, a dielectric CMP step to remove a portion of a surface of the substrate after the barrier CMP step is performed.

In one embodiment of the present invention, a third anneal step is performed to the substrate after the first anneal step and before the metal CMP step are performed.

In one embodiment of the present invention, the first temperature range is in a range of about 100° C. to about 350° C., and the second temperature range is in a range of about 250° C. to about 450° C.

In one embodiment of the present invention, the first environment or the second environment comprises a vacuum environment or an environment comprising a nitrogen gas, a hydrogen gas and a forming gas.

In one embodiment of the present invention, the first anneal step is performed in a range of about 1 minutes to about 5 minutes, and the second anneal step is performed in a range of about 1 minutes to about 60 minutes.

In one embodiment of the present invention, the second anneal step comprises a furnace anneal, a lamp anneal or a hot plate anneal.

In accordance with one embodiment of the present invention, a multi-step anneal method is provided. First, a substrate is provided. Then, a dielectric layer comprising a damascene structure is formed over the substrate, and a barrier/seed layer is formed over the damascene structure. Thereafter, a metal layer is formed over the barrier layer. A first anneal step is further performed to anneal the substrate at a first temperature range in a first environment, for example, a vacuum environment or a gas environment comprising a nitrogen gas, a hydrogen gas and a forming gas. Thereafter, a metal chemical mechanical polish (CMP) step is performed to remove a portion of the metal layer until a portion of the barrier layer is exposed, and then a second anneal step is performed to anneal the substrate at a second temperature range in a second environment.

In one embodiment of the present invention, a barrier CMP step is performed to remove the portion of the barrier layer and a surface of the metal layer until a portion of dielectric layer is exposed after the second anneal step is performed.

In one embodiment of the present invention, a dielectric CMP step is performed to remove a portion of a surface of the substrate after the barrier CMP step is performed.

In one embodiment of the present invention, a third anneal step is performed to the substrate after the first anneal step and before the metal CMP step is performed.

In one embodiment of the present invention, the first temperature range is in a range of about 100° C. to about 350° C., and the second temperature range is in a range of about 250° C. to about 450° C.

In one embodiment of the present invention, the second environment comprises the vacuum environment or the gas environment.

In one embodiment of the present invention, the first anneal step is performed for about 1 minutes to about 5 minutes, and the second anneal step is performed for about 1 minutes to about 60 minutes.

In one embodiment of the present invention, the second anneal step comprises a furnace anneal, a lamp anneal or a hot plate anneal.

In accordance with another embodiment of the present invention, a multi-step anneal method is provided. First, a substrate is provided. Then, a dielectric layer comprising a damascene structure is formed over the substrate, and a barrier/seed layer is formed over the damascene structure. A metal layer is further formed over the barrier layer, and a first anneal step is performed in-situ to anneal the substrate at a first temperature range in a first environment. Thereafter, a metal chemical mechanical polish (CMP) step is performed to remove a portion of the metal layer until a portion of the barrier layer is exposed. A barrier CMP step is further performed to remove the portion of the barrier layer and a surface of the metal layer until a portion of dielectric layer is exposed. Then, a second anneal step is performed to anneal the substrate at a second temperature range in a second environment.

In one embodiment of the present invention, a dielectric CMP step to remove a portion of a surface of the substrate after the barrier CMP step is performed.

In one embodiment of the present invention, a third anneal step is performed to the substrate after the first anneal step and before the metal CMP step are performed.

In one embodiment of the present invention, the first temperature range is in a range of about 100° C. to about 350° C., and the second temperature range is in a range of about 250° C to about 450° C.

In one embodiment of the present invention, the first environment or the second environment comprises a vacuum environment or an environment comprising a nitrogen gas, a hydrogen gas and a forming gas.

In one embodiment of the present invention, the first anneal step is performed in a range of about 1 minutes to about 5 minutes, and the second anneal step is performed in a range of about 1 minutes to about 60 minutes.

In one embodiment of the present invention, the second anneal step comprises a furnace anneal, a lamp anneal or a hot plate anneal.

In accordance with yet another embodiment of the present invention, a multi-step anneal method is provided. First, a substrate is provided. Then, a dielectric layer comprising a damascene structure is formed over the substrate, and a barrier/seed layer is formed over the damascene structure. A metal layer is further formed over the barrier layer, and a first anneal step is performed in-situ to anneal the substrate at a first temperature range in a first environment. Thereafter, a metal chemical mechanical polish (CMP) step is performed to remove a portion of the metal layer until a portion of the barrier layer is exposed. A barrier CMP step is further performed to remove the portion of the barrier layer and a surface of the metal layer until a portion of dielectric layer is exposed. Then, a dielectric CMP step is performed to remove a portion of a surface of the substrate. Thereafter, a second anneal step is performed to anneal the substrate at a second temperature range with a second environment.

In one embodiment of the present invention, a third anneal step is performed to the substrate after the first anneal step and before the metal CMP step are performed.

In one embodiment of the present invention, the first temperature range is in a range of about 100° C. to about 350° C., and the second temperature range is in a range of about 250° C. to about 450° C.

In one embodiment of the present invention, the first environment or the second environment comprises a vacuum environment or an environment comprising a nitrogen gas, a hydrogen gas and a forming gas.

In one embodiment of the present invention, the first anneal step is performed in a range of about 1 minutes to about 5 minutes, and the second anneal step is performed in a range of about 1 minutes to about 60 minutes.

In one embodiment of the present invention, the second anneal step comprises a furnace anneal, a lamp anneal or a hot plate anneal.

Accordingly, since the present invention provides the first anneal step, the second anneal step or the third anneal step, the grain growth of the metal layer is stabilized, and the tensile stress of the metal layer is released and uniform. Therefore, the hillocks of the semiconductor structure are reduced and the metal CMP process is easily controlled. In addition, since the close loop controlled (CLC) measurement may also be performed after the second anneal step, the thickness and the polishing time of the layers of the substrate can be precisely controlled. Therefore, the metal resistance (Rs) of the structure can also be controlled.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1B are schematic cross-sectional views of a conventional copper dual damascene structure.

FIG. 2 is a schematic cross-sectional view of a copper damascene structure according to one embodiment of the present invention.

FIG. 3A to FIG. 3C are schematic cross-sectional views of a damascene structure illustrating a flow of a planarization process of the damascene structure shown in FIG. 2 according to one embodiment of the present invention.

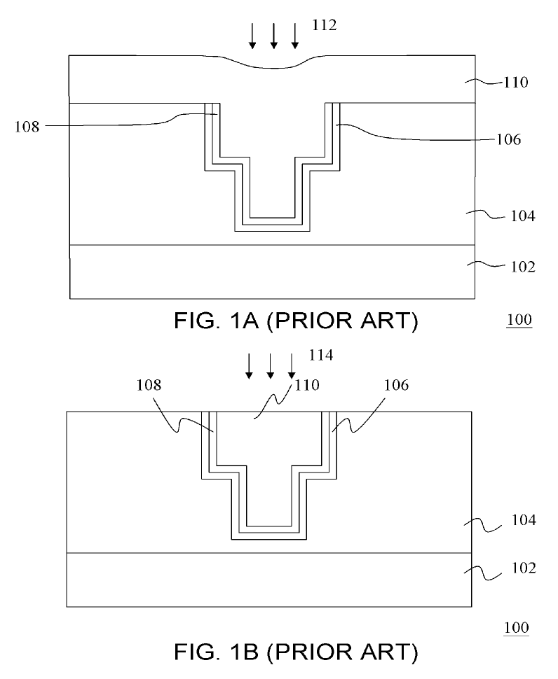

### DESCRIPTION OF THE EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

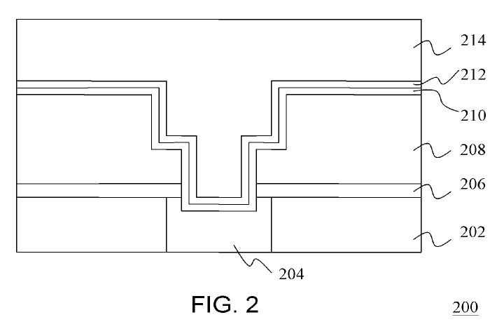

FIG. 2 is a schematic cross-sectional view of a copper damascene structure according to one embodiment of the present invention. The structure 200 shown in FIG. 2 is a portion of a semiconductor structure comprising at least one damascene structure formed over a substrate. First of all, a dielectric layer 202, a metal layer 204 and a cap layer 206 are formed. The dielectric layer 202 comprises, for example but not limited to, an inter-metal dielectric layer. The metal layer 204 may be the N^{th} metal layer, for example, the first metal layer (M1 layer), the second metal layer (M2 layer), and so on. After the metal layer 204 is planarized by, for example, a chemical mechanical polishing (CMP) process, the cap layer 206 is formed over the metal layer 204.

Next, referring to FIG. 2, a dielectric layer 208 is formed over the cap layer 206. The dielectric layer 208 comprises, for example but not limited to, an inter-metal dielectric layer. Then, the dielectric layer 208 and the cap layer 206 are patterned and etched to form a damascene structure comprising, for example, a single damascene structure or a dual damascene structure. It is noted that the cap layer 206 is etched to expose the metal layer 204. Thereafter, a barrier layer 210 is formed over the sidewall of the damascene structure, a seed layer 212 is formed over the barrier layer 210, and then the metal layer 214 is formed. The barrier layer 210 may be used as a barrier to avoid the diffusion between the metal layer 214 and the dielectric layer 208. The seed layer may be used to enhance the adhesion of the metal layer 214 to the dielectric layer 208. The metal layer 214 may be, for example but not limited to, a copper layer formed by using an electro-chemical plating (ECP) method. The metal layer 214 may be the (N+1)^{th} metal layer. It is note that, the metal layer 214 may also be the first metal layer, therefore the metal layer 204 may be, for example but not limited to, a contactor a via. In addition, the present invention may also be provided for a structure 200 with only one single metal layer 214.

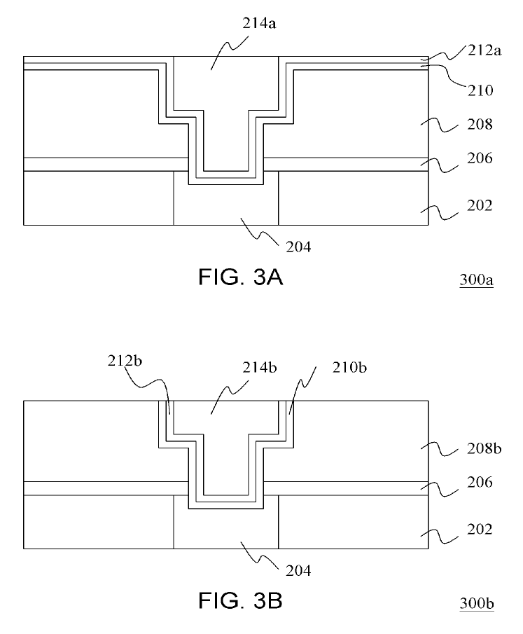

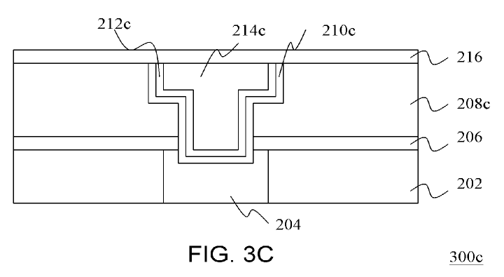

FIG. 3A to FIG. 3D are schematic cross-sectional views illustrating a flow of a planarization process of a damascene structure according to one embodiment of the present invention.

In one embodiment of the present invention, referring to FIG. 2, a first anneal step may be performed in-situ at a first temperature range and in a first environment to anneal the structure 200 of the substrate during the metal layer 214 is formed. The first anneal step is performed, for example but not limited to, by using lamp or hot plate. The first temperature range comprising, for example but not limited to, a range of about 100° C. to about 350° C. The first environment comprises, for example but not limited to, a vacuum environment or a gas environment comprising a nitrogen gas, a hydrogen gas and a forming gas (i.e., a mixture of nitrogen gas and a hydrogen gas). In addition, the first anneal step is performed for about 1 minutes to about 5 minutes.

In another embodiment of the present invention, referring to FIG. 2, another first anneal step may be performed to anneal the structure 200 of the substrate after the metal layer 214 is formed. The process parameters of the another first anneal step is similar or identical to that of the first anneal step, and thus will not be repeated.

Next, referring to FIG. 3A, a metal chemical mechanical polish (CMP) step may be performed to the structure 200 to remove a portion of the metal layer 214 until a portion of the seed layer 212 or the barrier layer 210 is exposed. The polished structure 200, the polished metal layer 214 and the polished seed layer 212 are referred to as a structure 300a, a metal layer 214a and a seed layer 212a.

Thereafter, a second anneal step is performed to anneal the structure 300a at a second temperature range in a second environment. The second anneal step is performed, for example but not limited to, by using furnace, lamp or hot plate. The second temperature range comprises, for example but not limited to, a range of about 250° C. to about 450° C. The second environment comprises, for example but not limited to, a vacuum environment or a gas environment comprising a nitrogen gas, a hydrogen gas and a forming gas. Moreover, the second anneal step is performed for about 1 minutes to about 60 minutes.

Optionally, it is noted that, after the first anneal step and before the metal CMP step, a third anneal step may be further provided at a third temperature range in a third environment. The third anneal step is performed, for example but not limited to, by using furnace, lamp or hot plate. The third temperature range comprises, for example but not limited to, a range of about 100° C. to about 350° C. The second environment comprises, for example but not limited to, a vacuum environment or a gas environment comprising a nitrogen gas, a hydrogen gas and a forming gas. Moreover, the second anneal step is performed for about 1 minutes to about 60 minutes.

Thereafter, after the second anneal step, a barrier CMP step may be provided to the structure 300a to remove a portion of the seed layer 212a, the barrier layer 21 0 and the metal layer 214a until a portion of dielectric layer 208 is exposed. The polished structure 300a, the polished metal layer 214a, the polished seed layer 212a, the polished barrier layer 210 and the polished dielectric layer 208 are referred to as a structure 300b, a metal layer 214b, a seed layer 212b, a barrier layer 210b and a dielectric layer 208b.

After barrier CMP step, a dielectric CMP step may be provided to the structure 300b to remove a portion of the seed layer 212b, the barrier layer 210b and the metal layer 214b and the dielectric layer 208b to planarize the surface of the substrate. Then, a cap layer may be formed over the surface of the substrate. The reference of the polished structure and the polished layer are shown in FIG. 3C.

In another embodiment of the present invention, the second anneal step may also be performed after the structure 300b shown in FIG. 3B is formed to anneal the structure 300b at a second temperature range in a second environment. The process parameter of the second anneal step is similar or identical to that described above, and will not repeat herein. It is noted that, in the present embodiment, the first anneal step may be performed in-situ with the step of forming a metal layer, or after the metal layer is formed. In addition, the third anneal step may also be optionally performed to the substrate after the first anneal step and before the metal CMP step. The subsequent processes of the present invention are also similar or identical to those described above, and will not repeat herein.

It should be noted that, in the present embodiment, a close loop controlled (CLC) measurement may also be performed after the second anneal step to measure, for example, the thickness of the dielectric layer. Therefore, the thickness of the dielectric layer and the polishing time of the structure 300b may be precisely controlled, and thus the metal resistance (Rs) of the structure may also be controlled.

In one another embodiment of the present invention, the second anneal step may also be performed after the structure 300c shown in FIG. 3B is formed to anneal the structure 300c at a second temperature range in a second environment. The process parameter of the second anneal step is similar or identical to that described above, and will not repeat herein. It is noted that, in the present embodiment, the first anneal step may be performed in-situ with the step of forming a metal layer, or after the metal layer is formed. In addition, the third anneal step may also be optionally performed to the substrate after the first anneal step and before the metal CMP step. The subsequent processes of the present invetnion are also similar or identical to that described above, and will not not repeat herein.

Accordingly, since the present invention provides the first anneal step, the second anneal step or the third anneal step, the grain growth of the metal layer is stabilized, and the tensile stress of the metal layer is released and uniformed. Therefore, the hillocks of the semiconductor structure are reduced and the metal CMP process is easy to be controlled. In addition, since the close loop controlled (CLC) measurement may also be performed after the second anneal step, the thickness and the polishing time of the layers of the substrate may be precisely controlled. Therefore, the metal resistance (Rs) of the structure may also be controlled.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A multi-step anneal method, comprising:
providing a substrate;
forming a dielectric layer comprising a damascene structure over the substrate;
forming a barrier/seed layer over the damascene structure;
forming a metal layer over the barrier layer, and performing a first anneal step in-situ to anneal the substrate at a first temperature range in a first environment;
performing a metal chemical mechanical polish (CMP) step to remove a portion of the metal layer until a portion of the barrier layer is exposed; and
performing a second anneal step to anneal the substrate at a second temperature range with a second environment.

2. The multi-step anneal method of claim 1, wherein after the second anneal step further comprising:
performing a barrier CMP step to remove the portion of the barrier layer and a surface of the metal layer until a portion of dielectric layer is exposed.

3. The multi-step anneal method of claim 2, wherein after the barrier CMP step further comprising:
performing a dielectric CMP step to remove a portion of a surface of the substrate.

4. The multi-step anneal method of claim 1, wherein after the first anneal step and before the metal CMP step further comprising:
performing a third anneal step to the substrate.

5. The multi-step anneal method of claim 1, wherein the first temperature range is in a range of about 100° C. to about 350° C., and the second temperature range is in a range of about 250° C. to about 450° C.

6. The multi-step anneal method of claim 1, wherein the first environment or the second environment comprises a vacuum environment or an environment comprising a nitrogen gas, a hydrogen gas and a forming gas.

7. The multi-step anneal method of claim 1, wherein the first anneal step is performed for about 1 minutes to about 5 minutes, and the second anneal step is performed for about 1 minutes to about 60 minutes.

8. The multi-step anneal method of claim 1, wherein the second anneal step comprises a furnace anneal, a lamp anneal or a hot plate anneal.

9. The multi-step anneal method of claim 1, further comprising performing a close loop control (CLC) measurement after the second anneal step.

10. A multi-step anneal method, comprising:
providing a substrate;
forming a dielectric layer comprising a damascene structure over the substrate;
forming a barrier/seed layer over the damascene structure;
forming a metal layer over the barrier layer;
performing a first anneal step to anneal the substrate at a first temperature range in a vacuum environment or a gas environment comprising a nitrogen gas, a hydrogen gas and a forming gas;
performing a metal chemical mechanical polish (CMP) step to remove a portion of the metal layer until a portion of the barrier layer is exposed; and
performing a second anneal step to anneal the substrate at a second temperature range in a second environment.

11. The multi-step anneal method of claim 10, wherein after the second anneal step further comprising:
performing a barrier CMP step to remove the portion of the barrier layer and a surface of the metal layer until a portion of dielectric layer is exposed.

12. The multi-step anneal method of claim 11, wherein after the barrier CMP step further comprising:
performing a dielectric CMP step to remove a portion of a surface of the substrate.

13. The multi-step anneal method of claim 10, wherein after the first anneal step and before the metal CMP step further comprising:
performing a third anneal step to the substrate.

14. The multi-step anneal method of claim 10, wherein the first temperature range is in a range of about 100° C. to about 350° C., and the second temperature range is in a range of about 250° C. to about 450° C.

15. The multi-step anneal method of claim 10, wherein the second environment comprises the vacuum environment or the gas environment.

16. The multi-step anneal method of claim 10, wherein the first anneal step is performed in a range of about 1 minutes to about 5 minutes, and the second anneal step is performed in a range of about 1 minutes to about 60 minutes.

17. The multi-step anneal method of claim 10, wherein the second anneal step comprises a furnace anneal, a lamp anneal or a hot plate anneal.

18. The multi-step anneal method of claim 10, after the second anneal step further comprising:
a close loop controlled (CLC) measurement.

19. A multi-step anneal method, comprising:
providing a substrate;
forming a dielectric layer comprising a damascene structure over the substrate;
forming a barrier/seed layer over the damascene structure;
forming a metal layer over the barrier layer, and performing a first anneal step to anneal the substrate at a first temperature range in a first environment;
performing a metal chemical mechanical polish (CMP) step to remove a portion of the metal layer until a portion of the barrier layer is exposed;
performing a barrier CMP step to remove the portion of the barrier layer but the dielectric layer is not exposed yet; and
performing a second anneal step to anneal the substrate at a second temperature range in a second environment after the dielectric CMP step.

20. The multi-step anneal method of claim 19, wherein after the first anneal step and before the metal CMP step further comprising:
performing a third anneal step to the substrate.

21. The multi-step anneal method of claim 19, wherein the first anneal step is performed in-situ with the step of forming a metal layer, or after the metal layer is formed.

22. The multi-step anneal method of claim 19, wherein the first temperature range is in a range of about 100° C. to about 350° C., and the second temperature range is in a range of about 250° C. to about 450° C.

23. The multi-step anneal method of claim 19, wherein the first environment or the second environment comprises a vacuum environment or a gas environment comprising a nitrogen gas, a hydrogen gas and a forming gas.

24. The multi-step anneal method of claim 19, wherein the first anneal step is performed for about 1 minutes to about 5 minutes, and the second anneal step is performed for about 1 minutes to about 60 minutes.

25. The multi-step anneal method of claim 19, wherein the second anneal step comprises a furnace anneal, a lamp anneal or a hot plate anneal.

26. The multi-step anneal method of claim 19, further comprising performing a close loop control (CLC) measurement after the second anneal step.
